(19) United States
(12) Patent Application Publication
(10) Pub. No.: US 2011/0081519 A1
(43) Pub. Date: Apr. 7, 2011

(54) PROCESS FOR ADJUSTING THE COEFFICIENT OF FRICTION AND/OR ADHESION BETWEEN SURFACES OF TWO SOLID OBJECTS

(75) Inventors: Elbert Christiaan Dillingh, Pijnacker (NL); Chretien Guillaume Maria Hermse, Geldrop (NL); Albertus Josef Huis in't Veld, Waalrre (NL)

(73) Assignee: NEDERLANDSE ORGANISATIE VOOR TOEGEPAST-NATUURWETEN, DELFT (NL)

(21) Appl. No.: 12/920,942

(22) PCT Filed: Mar. 6, 2009
(86) PCT No.: PCT/NL09/50101

§ 371 Date: Dec. 3, 2010

(30) Foreign Application Priority Data
Mar. 7, 2008 (EP) 08152451.4

(51) Int. Cl. B32B 3/00; H01L 41/22

(52) U.S. Cl. 428/141; 29/25.35

(57) ABSTRACT

The invention provides a process for adjusting the friction coefficient and adhesion between a surface of a first solid object and a surface of a second solid object, which surfaces are movable with respect to each other when the solid objects are in contact with each other, wherein the surface roughness of at least one of the surfaces is adjusted by subjecting one or more selected parts of said first and/or second solid objects to an electric field and/or a magnetic field, wherein at least said one or more selected parts of said first and/or second solid objects comprise a piezo-electric material, and wherein other parts of said first and/or second solid object do not comprise a piezo-electric material. The invention further provides an object having a surface of which the roughness can be adjusted by subjecting one or more selected parts of the object to an electric field and/or a magnetic field, which selected parts comprise a piezo-electric material. In addition, the invention provides a system comprising said object.

The present invention relates to a process for adjusting the coefficient of friction between a surface of a first solid object and a surface of a second solid object.

Movement between two bodies in contact is inherently connected with conversion of kinetic energy to heat. Friction forces are responsible for this energy loss and generally cause wear of the components that are in contact. Optimisation of the properties of friction surfaces and lubricating films between friction surfaces to minimise friction therefore is of high economic significance. The adjustment of friction is conventionally achieved by using appropriate surface coatings and texturing/adapting the surface roughness and/or by the use of lubricants.

However, it is not possible to deliberately and continuously adjust in this way the friction coefficient between two bodies, and/or to vary it as a function of time. In addition, it is not possible with ordinary methods to reversibly change or control the friction coefficient as a function of location.

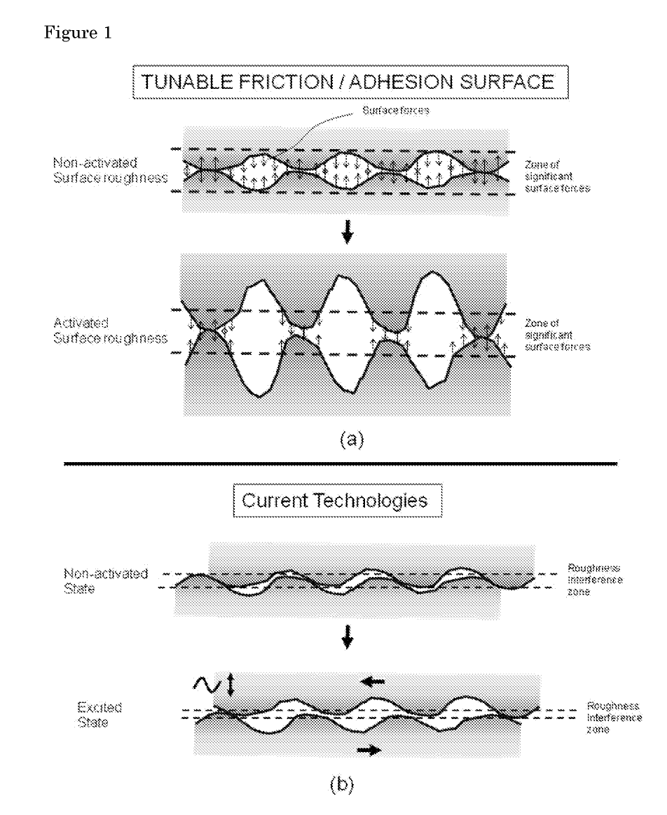

Friction is also of central significance in micro-engineering. Due to the small sizes of the components, the surface properties of the components become very important and a change friction can have serious consequences. A control over the friction could e.g. deliberately allow moving or fixing certain components or objects. There exists several ways to adapt friction in situ, though not so much for adhesion. Current technologies make use of a dynamically excited surface to reduce the so-called roughness interference zone or thickness, see FIG. 1b. The current invention on the other hand is based on a completely different strategy as depicted in FIG. 1a. In the current invention the surface roughness is changed reducing the effect of surface forces.

It is for instance well appreciated that the manufacturers of high-end products such as semi-conductors and optical systems requires the use of equipment wherein use is made of very flat and smooth surfaces. For instance, in the manufacture of semi-conductors, the surface of a silicon wafer and a wafer-handling surface (e.g. clamps) need to be very flat and smooth. The use of very flat and smooth surfaces has, however, the disadvantage that after contact is established the silicon wafer and wafer-handling surface can only be separated by means of high mechanical force due to the high surface adhesive forces between the surfaces (Van der Waals and capillary forces). As a result of the high mechanical force that is required to separate both surfaces, the surfaces can be damaged which affects the reproducibility of the high-end equipment used.

Moreover, it is difficult to position objects relative to each other once they have touched, without physically separating the two objects again.

Object of the present invention is to provide an improved process and system for the production of high-end products that attractively deals with the above-mentioned problems.

Surprisingly, it has now been found that this can be established when the friction coefficient between the surfaces is adjusted by means of a material having a surface roughness that changes when the material is subjected to a suitable external stimulus.

Accordingly, the present invention relates to a process for adjusting the friction coefficient between a surface of a first solid object and a surface of a second solid object, which surfaces are movable with respect to each other when the solid objects are in contact with each other, wherein the surface roughness of at least one of the surfaces is adjusted by subjecting one or more selected parts of at least said first and/or second solid objects to an electric field and/or a magnetic field, wherein at least said one or more selected parts of said first and/or second solid objects comprise a piezo-electric material, and wherein other parts of said first and/or second solid object do not comprise a piezo-electric material.

Current technology for in situ adaptation of friction deals with excitation of one or both of the surfaces, in many cases with the use of piezo-electric or magnetostrictive materials. The general idea is that by excitation of the surface(s), the interlocking asperities (roughness peaks) will be, on average, further apart thus less hampering the lateral motion. In this way it is even possible by inducing a surface wave to create relative movement of the two contacting bodies. This differs significantly from the current invention, because the key of the current invention is not to increase the average separation of the surfaces in a highly dynamic way but in a (quasi) static way. In the current technologies the bouncing surfaces are most of the time separated and hover for some short time while allowing lateral movement. The current invention on the other hand is based on another physical principle, namely the short distances over which surface forces, like Van-der-Waals and capillary forces, can act. By changing actively and quasi-static the surface roughness, the two contacting bodies will be moved in or out of these active surface force regimes.

There are several advantages to this invention. First of all the static nature enables positioning at the nanometre level. Another advantage is that high contact stresses can be prevented unlike in the cases with bouncing surfaces. The invention can therefore also prevent the occurrence of particles forming by the damaging effect of bouncing over a prolonged use. Particles form a large problem in super clean environments like in semi-conductor industry and optics. By the ever increasing precision demanded in these industries, the prevention of particles is of paramount significance. A third advantage lies in the field of accurate positioning. In current technologies, accurate (nanometer precision) positioning of the objects relative to each other is impossible, since at least one of the surfaces is vibrating. Such accurate positioning is very attractive, because lithography takes place at smaller and smaller scale. Because of the static character of the roughness of the invention, accurate positioning is now becomes possible.

In accordance with the present invention the surface of a silicon wafer and a wafer-handling surface can very easily be separated from each other after use, thus avoiding that the surfaces will be damaged and ensuring an attractive reproducibility of the high-end system over a longer period of time.

It also enables easier positioning of the silicon wafer and the wafer-handling surface with respect to each other.

Suitable examples of piezo-electric materials include lead zirconate titanate (PZT), lead magnesium niobate (PMN), lead niobate (LMN), lead titanate (PT), bismuth titanate, barium titanate, lead metaniobate, potassium niobate, lithium niobate, lithium tantalate, sodium tungstate and polyvinylidene fluoride (PVFD). Preferably the piezo-electric material is PZT or PVFD. More preferably, the piezo-electric material is PZT.

The one or more selected parts that comprise the piezo-electric materials can comprise a further material that expands or changes in volume when the selected parts are subjected to direct current or electric field. Such materials e.g. include suitable metal alloys, shape memory alloys, magnetorestrictive materials and polymers.

Suitable examples of shape memory metal alloys include, copper-zinc-aluminium-nickel, copper-aluminium-nickel, nickel-titanium (NiTi) alloys. Preferably, the shape memory alloy is copper-zinc-aluminium-nickel or NiTi. More preferably, the shape memory alloy is copper-zinc-aluminium-nickel. Preferably, the metal alloy is an iron-nickel-chromium-molybdenum alloy or an iron-aluminium-chromium-molybdenum alloy. More preferably, the metal alloy is a iron-nickel-chromium-molybdenum alloy.

Suitable examples of magnetostrictive materials are iron, cobalt, nickel and terfenol-D. Preferably the magnetostrictive material is terfenol-D.

Suitable examples of polymers are polyethylene, polypropylene, polyvinylchloride, polyurethane, polyethyleneterephtalate, polyester, polyamines. Preferably, the polymer is polyethylene.

In accordance with the present invention suitably one or more selected parts of one of the objects are subjected to an electric field and/or a magnetic field.

Preferably, two or more selected parts of at least one of the objects are subjected to an electric and/or a magnetic field.

Suitably, the piezo-electric material has the form of a uniform layer within at least one of the objects which layer is arranged near the surface of the at least one object.

In accordance with the present invention an electric field and/or a magnetic field is applied. When an electric field is used, the electric field strength can suitably be in the range of from 0-3 000 000 V/m. Preferably, the electric field strength is in the range of from 0-30 000 V/m. Above 30 000 V/m there is a risk of electrical discharge due to exceeding the breakdown voltage. When a magnetic field is used, the magnetic field strength can suitably be in the range of from 0-5 Tesla. Preferably, the magnetic field strength is in the range of from 0-1.5 Tesla. Magnetic fields of higher than 1.5 Tesla are not practical.

Further external stimuli that can be applied to the one or more selected parts include heat, and electro-magnetic radiation.

Suitably, in the process of the present invention the surface roughness of at least one of the surfaces increases. Preferably, the surface roughness of only one of the surfaces increases.

The objects can have a multi-layer structure wherein at least one of the layers comprises the piezo-electric material.

In a particularly attractive embodiment of the invention the adjustment of the friction coefficient between the surfaces of the first and second object is reversible, establishing an attractive reproducibility over a prolonged period of time.

In another very attractive embodiment of the present invention the adjustment of the friction coefficient is directionally dependent. This means that objects can be aligned in one direction while maintaining relative orientation in the other direction, preferably perpendicular to the direction of alignment. This can be done by creating specific shaped zones with the described active surface properties while leaving other areas unchanged. This allows low friction movement in only one direction

Suitably, in accordance with the present invention, the first object is a silicon wafer and the second object is a wafer-handling surface. The term “wafer handling surface” as used in this application is meant to refer to the wafer contacting surfaces which are meant to keep a wafer in position during the lithographic process and/or surfaces that are used to transport or position the silicon wafers in the machine. It is preferred that at least one or more selected parts of the wafer-handling surface are subjected to the magnetic or the electric field.

Other suitable first objects include reticles (masks) and wafers. Other suitable second objects include reticle clamps and wafer clamps.

The present invention also provides a solid object having a surface of which the roughness can be adjusted by subjecting one or more selected parts of the object to an electric field and/or a magnetic field, which selected parts comprise a piezo-electric material.

Preferably, the surface roughness of the surface of the object increases.

In accordance with the present invention the object has preferably a multi-layer structure wherein at least one of the layers comprises the piezo-electric material.

Preferably, the material has the form of a uniform layer within the object which layer is arranged near the surface of the object.

In a particularly attractive embodiment of the invention, the adjustment of the roughness of the surface of the object is reversible. In another very attractive embodiment of the present invention, the adjustment of the friction coefficient is directionally dependent.

Preferably, the object is a wafer-handling surface. In an embodiment, the object is a reticle clamp surface. A reticle is the pattern tool used in lithography in semi-conductor industry.

The present invention further provides a system that comprises two or more objects of which at least one object is the object in accordance with the present invention.

Preferably, the system in accordance with the present invention comprises a high-end equipment system that comprises a silicon wafer and a wafer-handling surface in accordance with the present invention. The term “high-end equipment system” as used herein is meant to refer to a system developed for lithographic applications, optics and space applications.

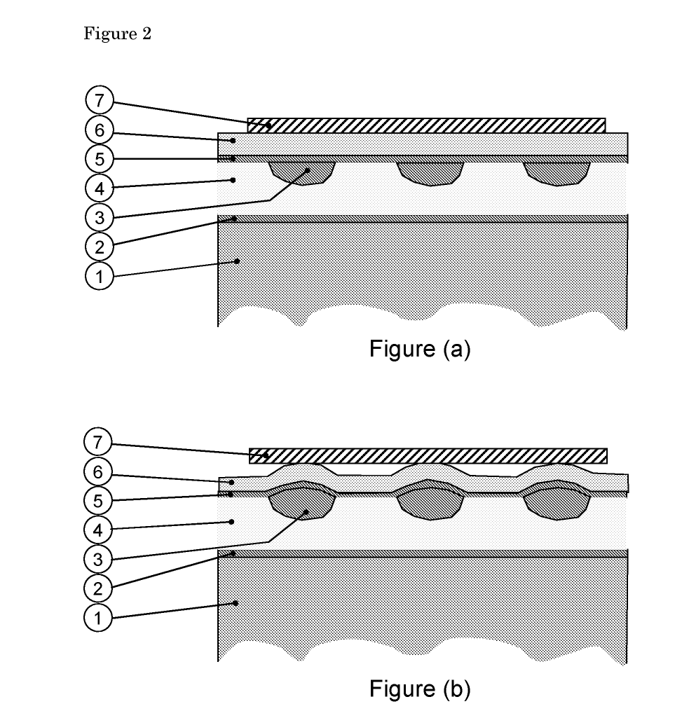

The invention will now be illustrated by means of FIG. 2 wherein (1) is the substrate of the clamp, (2) and (5) are respectively the lower and upper electrode which span an electric field over the PZT material (3) and (4). The PZT-material is divided into two phases, (3) is the poled PZT-material and (4) is the unpoled PZT-material. The multi-layer can optionally finish with a top coating (6). Finally (7) is the object being clamped. In FIG. 2 two clamp states are shown. FIG. 2a shows the clamped condition (non-activated tunable friction/adhesion surface) while FIG. 2b shows the unclamped/released and/or low friction condition (activated tunable friction/adhesion surface).

1. A process for adjusting the friction coefficient and/or adhesion between a surface of a first solid object and a surface of a second solid object, which surfaces are movable with respect to each other when the solid objects are in contact with each other, wherein the surface roughness of at least one of the surfaces is adjusted by subjecting one or more selected parts of at least said first and/or second solid objects to an electric field and/or a magnetic field, wherein at least said one or more selected parts of said first and/or second solid objects comprise a piezo-electric material, and wherein other parts of said first and/or second solid object do not comprise a piezo-electric material.

2. The process according to claim 1, wherein two or more selected parts of said first and/or second solid object, said parts comprising a piezo-electric material, are subjected to an external stimulus.

3. The process according to claim 1, wherein the piezo-electric material has the form of a uniform layer within at least one of the objects which layer is arranged near the surface of the at least one object.

4. The process according to claim 1, wherein the surface roughness of at least one of the surfaces increases.

5. The process according to claim 1, wherein the objects have a multi-layer structure wherein at least one of the layers comprises the piezo-electric material.

6. The process according to claim 1, wherein the adjustment of the friction coefficient between the surfaces of the first and second object is reversible.

7. The process according to claim 1, wherein the adjustment of the friction coefficient is directionally dependent.

8. The process according to claim 1, wherein the first object is a silicon wafer and the second object is a wafer-handling surface.

9. The process according to claim 8, wherein at least one or more selected parts of at least the second object are subjected to the electric field and/or the magnetic field.

10. A solid object having a surface of which the roughness can be adjusted by subjecting one or more selected parts of the object to an electric field and/or a magnetic field, which selected parts comprise a piezo-electric material.

11. The object according to claim 10, wherein the roughness of the surface of the object increases.

12. The object according to claim 10, wherein the object has a multi-layer structure wherein at least one of the layers comprises the piezo-electric material.

13. The object according to claims 10, wherein the material has the form of a uniform layer within the object which layer is arranged near the surface of the object.

14. The object according to claim 10, which object is a wafer-handling surface.

15. The object according to claim 10, which object is a reticle clamp surface.

16. A system that comprises two or more objects of which at least one object is the object as defined in claim 10.

17. The system according to claim 15, which system is a high-end equipment system that comprises a silicon wafer and a wafer-handling surface, which wafer-handling surface is defined in claim 13.
